(19) United States
(12) Patent Application Publication
(10) Pub. No.: US 2011/0057198 A1
(43) Pub. Date: Mar. 10, 2011

(54) TECHNIQUE FOR DEVELOPMENT OF HIGH CURRENT DENSITY HETEROJUNCTION FIELD EFFECT TRANSISTORS BASED ON (10-10)-PLANE GaN BY DELTA-DOPING

(75) Inventors: Tetsuya Fujiwara, Santa Barbara, CA (US); Stacia Keller, Santa Barbara, CA (US); Umesh K. Mishra, Montecito, CA (US)

(73) Assignee: THE REGENTS OF THE UNIVERSITY OF CALIFORNIA, Oakland, CA (US)

(21) Appl. No.: 12/871,445

(22) Filed: Aug. 30, 2010

Related U.S. Application Data
(60) Provisional application No. 61/238,056, filed on Aug. 28, 2009.

(51) Int. Cl. H01L 29/20; H01L 29/737; H01L 21/338

(52) U.S. Cl. 257/76; 257/194; 438/172; 257/E29.188; 257/E29.089

(57) ABSTRACT

A delta (δ)-doped (10-10)-plane GaN transistor is disclosed. Delta doping can achieve a transistor having at least 10 times higher current density than a conventional (10-10)-plane GaN transistor.

### CROSS-REFERENCE TO RELATED APPLICATIONS

This application claims the benefit under 35 U.S.C. Section 119(e) of co-pending and commonly assigned U.S. Provisional Application Ser. No. 61/238,056, filed on Aug. 28, 2009, by Tetsuya Fujiwara, Stacia Keller, and Umesh K. Mishra, entitled “TECHNIQUE FOR DEVELOPMENT OF HIGH CURRENT DENSITY HETEROJUNCTION FIELD EFFECT TRANSISTORS BASED ON (10-10)-PLANE GaN BY DELTA-DOPING,” attorney's docket number 30794.312-US-P1 (2009-612-1), which application is incorporated by reference herein.

### STATEMENT REGARDING FEDERALLY SPONSORED RESEARCH AND DEVELOPMENT

This invention was made with Government support under Grant No. N00014-05-1-0419 awarded by the Office of Naval Research, MINE and MURI. The Government has certain rights in this invention.

### BACKGROUND OF THE INVENTION

1. Field of the Invention

This invention relates to nonpolar gallium nitride (GaN) based devices, and in particular delta-doped (δ-doped) (10-10)-plane GaN transistors.

2. Description of the Related Art

There exist expectations that (10-10)-plane GaN transistors should realize high threshold voltages, which are required for power switching devices. However, low current density (˜30 milliamps (mA)/millimeter(mm)) has been a problem for (10-10)-plane GaN transistors. More current, i.e. more power, is required for high power switching devices.

Thus, there is a need for increasing the current density on (10-10)-plane GaN transistors. The present invention satisfies that need.

### SUMMARY OF THE INVENTION

The present invention discloses an improved (10-10)-plane GaN transistor having a current density ten times higher than a conventional (10-10)-plane GaN transistor, which is obtained by delta-doping (δ-doping).

### BRIEF DESCRIPTION OF THE DRAWINGS

Referring now to the drawings in which like reference numbers represent corresponding parts throughout:

FIG. 1 is a cross-sectional schematic of a δ-doped (10-10)-plane GaN Heterojunction Field Effect Transistor (HFET) structure.

FIG. 2 plots the omega-2theta X-ray diffraction profile of (10-10)-plane AlGaN/GaN heterostructures (Intensity, in arbitrary units (a.u.) vs. 2theta in degrees (°)).

FIG. 3 is an atomic force microscope (AFM) image of the surface morphology of a (10-10)-plane AlGaN/GaN heterostructure.

FIG. 4 plots drain-source current (I_{ds}), in mA/mm, as a function of drain source voltage V_{ds}(I_{ds}V_{ds} characteristics) of δ-doped (10-10)-plane GaN HFETs.

FIG. 5 plots I_{ds}-V_{ds} characteristics of conventional (uniform-doped) (10-10)-plane GaN HFETs.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Fabrication

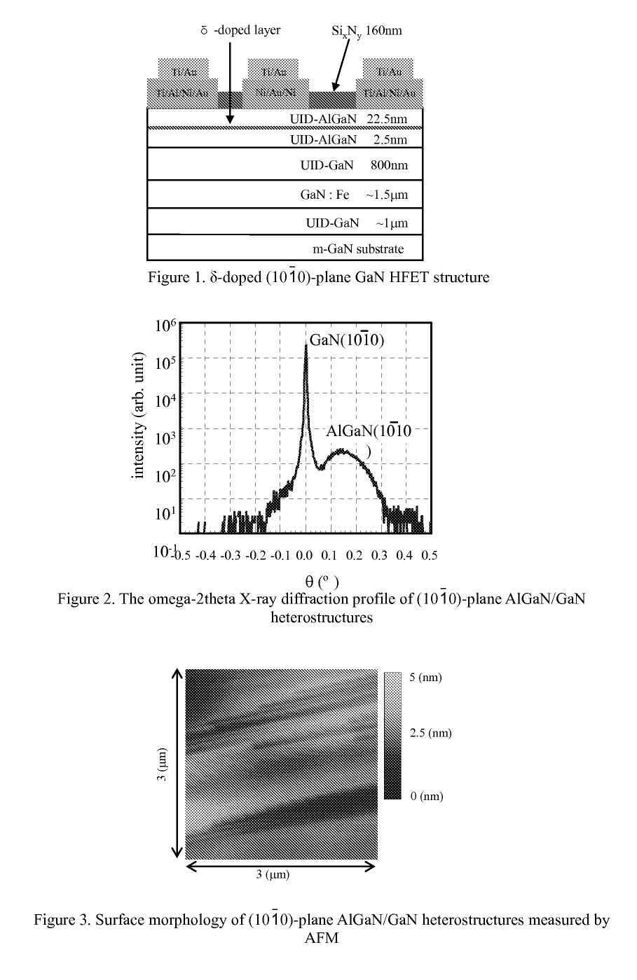

FIG. 1 shows the schematic structure of the δ-doped (10-10)-plane GaN HFET. The (10-10)-plane AlGaN/GaN heterostructure was grown by metal organic chemical vapor deposition on (10-10)-plane GaN substrates. The growth was initiated with the deposition of a 1 micrometer (μm) thick unintentionally doped (u.i.d.) GaN layer. Then, a 1.5-μm-thick Fe doped GaN layer was grown by using bis-cyclopentadienyl-iron. A 0.8-μm-thick u.i.d. GaN layer was grown as the channel layer. A 2.5 nanometer (nm) thick spacer Al_{0.32}Ga_{0.68}N layer was deposited. A δ-doped layer was formed by flowing SiH₄ and NH₃. A 22.5 nm-thick Al_{0.32}Ga_{0.68}N cap layer was deposited.

An omega-2theta X-ray diffraction profile of the epitaxial film is shown in FIG. 2.

A surface morphology image of the epitaxial film, taken by AFM, is shown in FIG. 3.

Ti(20 nm thick)/Al(120 nm thick)/Ni(30 nm thick)/Au(50 nm thick) stacks were deposited by e-beam evaporation as ohmic contact metals, and subsequently subjected to a rapid thermal annealing at 870° C. for 30 seconds in an N₂ atmosphere. A Cl₂ based dry etch was carried out for mesa isolation.

A Ni (30 thick)/Au(250 thick)/Ni(50 nm thick) stack was deposited by e-beam evaporation as the Schottky gate metal.

A 160 nm thick SiₓN_{y} passivation film was deposited by plasma-enhanced thermal chemical vapor deposition. The SiₓN_{y} was etched with CF₄ dry etching.

Ti(20 nm thick)/Au (250 nm thick) pad metals were deposited by e-beam evaporation.

Characterization

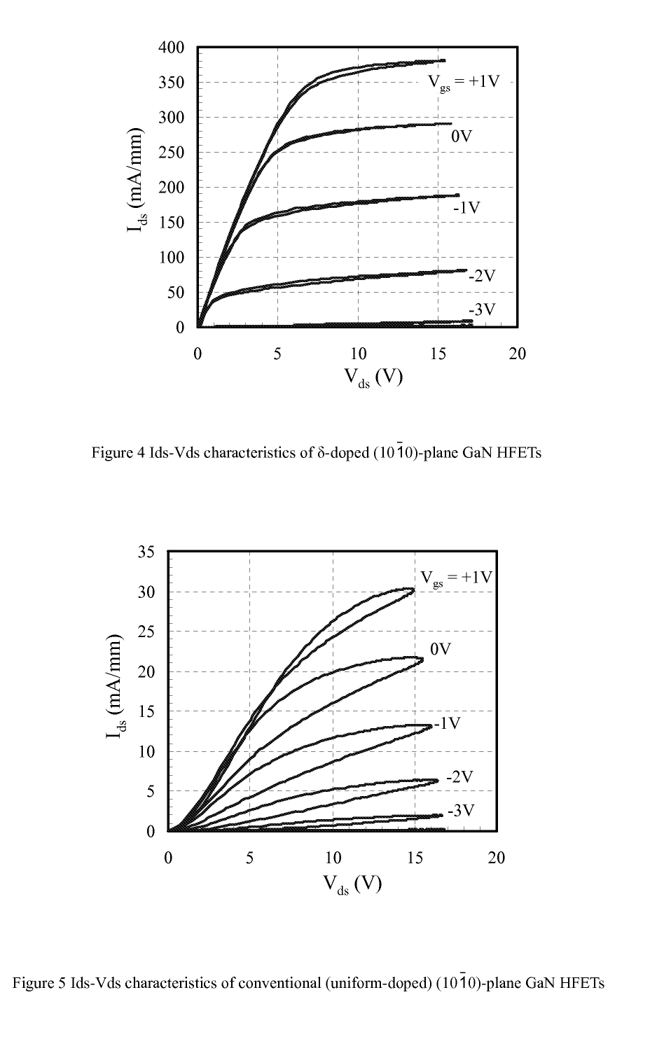

FIG. 4 shows the Ids-Vds characteristics of δ-doped (10-10)-plane GaN HFETs. 380 mA/mm of maximum drain current was obtained. FIG. 5 shows the Ids-Vds characteristics of conventional (uniform-doped) (10-10)-plane GaN HFETs. Therefore, at least 10 times higher current density was obtained by δ-doping. Further optimization of the present invention's device can increase the current density even further.

Possible Modifications

One possible for developing high current density (10-10)-plane GaN transistors is that (11-20)-plane GaN can be used instead of (10-10)-plane GaN described above, because (11-20)-plane GaN also has no polarization. Therefore, (11-20)-plane GaN transistors can also have high current density by delta doping.

Moreover, although the present invention is described as comprising GaN, other (Al,Ga,In)N materials may be used as well. The term “(Al,Ga,In)N” as used herein is intended to be broadly construed to include respective nitrides of the single species, Al, Ga, and In, as well as binary, ternary and quaternary compositions of such Group III metal species. These compounds are also referred to as Group III nitrides, or III-nitrides, or just nitrides, or by (Al,Ga,In)N, or by Al_{(1-x-y)}In_{y}GaₓN where 0≦x≦1 and 0≦y≦1.

Advantages and Improvements

The present invention has great advantages compared to the other ways for developing high current density (10-10)-plane GaN transistors. Usually, a uniform Si doped technique has been used to increase current density. However, parallel conduction occurred by increasing the Si doping concentration. In the present invention, the maximum carrier density without the parallel conduction was significantly improved by δ-doping, because the doping layer can be set at a close distance from the heterointerface that induces the two-dimensional-electron gas. For example, in delta-doping, all dopants are set within several nm of the interface, while in uniform doping, some dopants may exist more than 10 nm from the interface.

Appendix

Further information on the present invention can be found in the Appendix of the parent provisional application identified above and incorporated by reference herein, wherein the Appendix comprises a publication by Tetsuya Fujiwara, Stacia Keller, Masataka Higashiwaki, James S. Speck, Steven P. DenBaars, and Umesh K. Mishra, entitled “Si Delta-Doped m-Plane AlGaN/GaN Heterojunction Field-Effect Transistors,” found in Applied Physics Express, Vol. 2, No. 061003 (Jun. 12, 2009), and is incorporated by reference herein.

Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A transistor, comprising:
a III-nitride substrate having a surface that is a nonpolar plane of the III-nitride substrate; and
a III-nitride heterostructure residing on the surface of the III-nitride substrate, wherein the III-nitride heterostructure includes delta doping.

2. The transistor of claim 1, wherein:
the III-nitride heterostructure includes a higher bandgap layer and a lower bandgap layer, the higher bandgap layer has a higher bandgap than the lower bandgap layer, and the higher bandgap layer confines a two dimensional electron gas (2DEG) in the lower bandgap layer or at an interface with the lower bandgap layer;
the delta doping is a negatively charged delta doped layer in the higher bandgap layer of the III-nitride heterostructure that provides charge for the two dimensional electron gas.

3. The transistor of claim 2, wherein the delta doping is closer to the two dimensional electron gas than dopants in a uniformly doped transistor.

4. The transistor of claim 2, wherein the delta doping is sufficiently close to the interface so that a current density in the transistor is greater than 30 milliamps per millimeter.

5. The transistor of claim 2, wherein the delta doping is sufficiently close to the two dimensional electron gas to eliminate parallel conduction.

6. The transistor of claim 2, wherein the higher bandgap layer is AlGaN and the lower bandgap layer is GaN.

7. The transistor of claim 1, wherein the delta doping's concentration and position is such that that a current density in the transistor is at least ten times higher than a current density in a transistor that does not include delta doping, in order to provide charge to an active layer of the transistor.

8. The transistor of claim 1, wherein the delta doping's concentration and position is such that a current density in the transistor is more than 50 milliamps per millimeter.

9. The transistor of claim 1, wherein the surface of the III-nitride substrate is a (10-10) plane.

10. A method of fabricating a transistor, comprising:
delta doping a III-nitride heterostructure, wherein the III-nitride heterostructure is deposited on surface of a III-nitride substrate and the surface of the III-nitride substrate is a nonpolar plane of III-nitride.

11. The method of claim 1, wherein the delta doping achieves a current density at least 10 times higher than a transistor that is not delta doped.

12. A transistor, comprising:
a III-nitride substrate having a surface that is not a c-plane of the III-nitride substrate;
a III-nitride heterostructure residing on the surface of the III-nitride substrate, wherein the III-nitride heterostructure includes delta doping.

13. The transistor of claim 12, wherein the surface of the III-nitride substrate is a semipolar plane or other plane of the III-nitride substrate that has reduced polarization induced fields as compared to the c-plane of the III-nitride substrate.
